(19) United States
(12) Patent Application Publication
(10) Pub. No.: US 2014/0306712 A1
(43) Pub. Date: Oct. 16, 2014

(54) TRACKING AGING EFFECT ON BATTERY IMPEDANCE AND TRACKING BATTERY STATE OF HEALTH

(71) Applicant: BROADCOM CORPORATION, Irvine, CA (US)

(72) Inventor: Domitille Esnard-Domerego, BIOT (FR)

(73) Assignee: Broadcom Corporation, Irvine, CA (US)

(21) Appl. No.: 13/873,837

(22) Filed: Apr. 30, 2013

Related U.S. Application Data
(60) Provisional application No. 61/811,229, filed on Apr. 12, 2013.

(51) Int. Cl. G01R 31/36

(52) U.S. Cl. CPC G01R 31/3606
USPC 324/430; 324/426

(57) ABSTRACT

Methods and systems for tracking aging effect on battery impedance are provided. A first voltage associated with a first state of a battery, a second voltage associated with a second state of the battery, and an impedance of the battery are determined. A battery impedance table that is used for calculating a state of charge of the battery is updated using the determined impedance. Methods and systems for tracking state of health of a battery are also provided. Partial charge cycles of a received battery are counted between a first charge event and a second charge event of the battery. State of health data of the batter is tracked, and a new state of health estimation is calculated based on the state of health data if the counted partial charge cycles of the battery has a count value that has a predetermined relationship with a predetermined count threshold.

### CROSS REFERENCE TO RELATED APPLICATION

This application claims priority to U.S. Provisional Patent Application No. 61/811,229, filed Apr. 12, 2013, which is incorporated by reference herein.

### BACKGROUND

1. Technical Field

The subject matter described herein relates to rechargeable batteries, and in particular, to the tracking of battery aging and state-of-health.

2. Description of Related Art

A battery is a device that provides electrical energy used to power an electrical device. A battery typically includes one or more electrochemical cells that store chemical energy, which is converted to electrical energy output by the device to provide power. Batteries are used in a multitude of electrical devices, such as electrical devices that are mobile, are small, and/or are unable to be constantly connected to another power source such as AC (alternating current) power. Batteries may also be used in electrical devices as a backup power source that provides power when a primary power source is lost.

A rechargeable battery, such as a lithium-based battery, is a type of battery that is becoming increasingly popular. A rechargeable battery can be restored to full charge by the application of electrical energy. Techniques exist for determining an overall charge storage capacity of batteries (battery “state of health”) and a stored charge in batteries (battery “state of charge”).

For example, the state of charge of a rechargeable battery may be estimated based on a measured voltage of the battery and a determined impedance of the battery. Conventionally, a stored battery impedance table may be referenced for data that characterizes the impedance of a battery. However, as a battery ages, its impedance increases in a non-predictable manner. As such, the data contained in a battery impedance table may become increasingly inaccurate over time, resulting in the state of charge of the battery to be inaccurately estimated.

In another example, the state of charge of a battery may be determined based on the state of health of the battery. In this case, the accuracy of the state of charge is dependent on the accuracy of a determination of the state of health of the battery. Conventionally, the state of health may be estimated by counting the amount of charge flowing into the battery between a battery empty event and a battery full event, or counting the amount of charge flowing out of the battery between a battery full event and a battery empty event. However, such estimation can rarely be made because the batteries of portable devices are rarely allowed to be completely drained.

### BRIEF SUMMARY OF THE INVENTION

Methods and systems are described for tracking an aging effect on battery impedance and for tracking battery state of health substantially as shown in and/or described herein in connection with at least one of the figures, as set forth more completely in the claims.

### BRIEF DESCRIPTION OF THE DRAWINGS/FIGURES

The accompanying drawings, which are incorporated herein and form a part of the specification, illustrate the subject matter of the present application and, together with the description, further serve to explain the principles of the embodiments described herein and to enable a person skilled in the pertinent art to make and use such embodiments.

FIG. 1 shows a graphical representation of example charge characteristics of a battery.

FIG. 2 shows the battery of FIG. 1 during a charge/discharge period.

FIG. 3 shows example graphs illustrating the voltage and current of a battery over time during the transition from an idle state to an active state.

FIG. 4 shows different versions of an impedance table used for state of charge estimation, according to an example embodiment.

FIG. 5 shows a block diagram of a battery management system, according to example embodiments.

FIG. 6 is a flowchart providing a process for tracking aging effect on battery impedance, according to an example embodiment.

FIG. 7 shows a block diagram of an example of a battery management system for tracking aging effect on battery impedance, according to an example embodiment.

FIG. 8 shows a graph illustrating the estimated cumulated charges and the actual cumulated charges of a battery during multiple example partial charge and discharge cycles

FIG. 9 shows graphs illustrating a case where cumulated charges may be used for a state of charge estimation and a case where cumulated charges are not used for a state of charge estimation, according to an example embodiment.

FIG. 10 is a flowchart providing a process for tracking battery state of health, according to an example embodiment.

FIG. 11 shows a block diagram of an example of a battery management system for tracking state of health, according to an example embodiment.

FIG. 12 shows a block diagram of an electrical device that incorporates a battery manager, according to example embodiments.

The subject matter of the present application will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### A. Introduction

The following detailed description discloses numerous example embodiments. The scope of the present patent application is not limited to the disclosed embodiments, but also encompasses combinations of the disclosed embodiments, as well as modifications to the disclosed embodiments.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

### B. Example Battery Characteristics

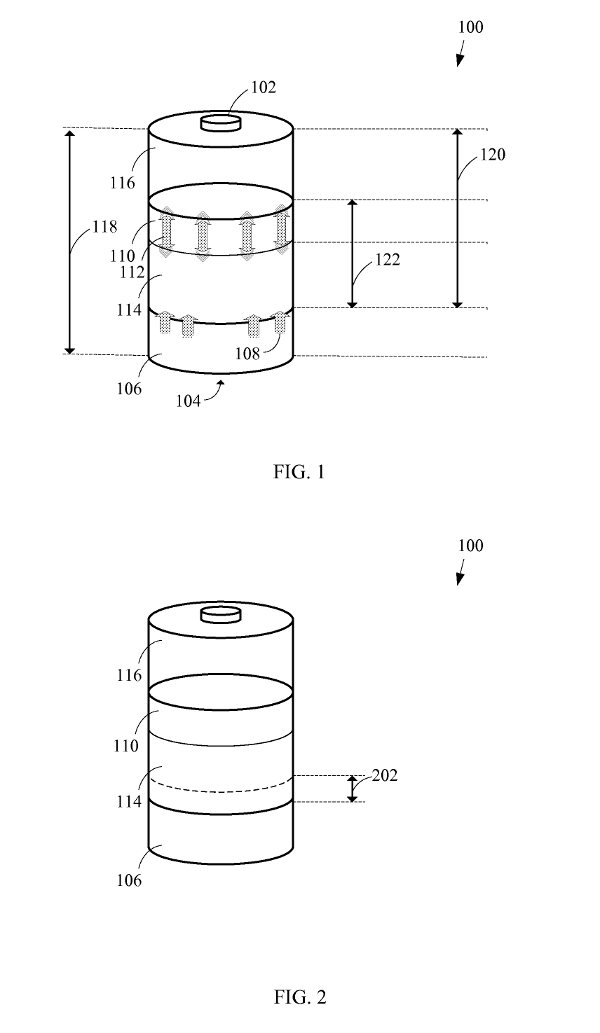

Embodiments disclosed herein relate to batteries. A battery is a device that provides electrical energy used to power an electrical device. A battery typically includes one or more electrochemical cells that store chemical energy, which is converted to electrical energy that is output by the device to provide power. FIG. 1 shows a representation of the charge characteristics of an example battery 100. Battery 100 has a first terminal 102 (e.g., negative or positive polarity) and a second terminal 104 (with polarity opposite that of first terminal 102). Battery 100 is a rechargeable battery formed of a material that enables recharging. For example, battery 100 may be a lithium-based rechargeable battery, such as a lithium ion (Li-ion) or lithium ion polymer (Li-ion polymer) battery. Rechargeable batteries can be restored to full charge by application of electrical energy.

The behavior of a lithium battery is complex, involving chemical reactions, reaction kinetics, and diffusions processes. Thus, a circuit equivalent model of a lithium battery is complex, as it typically includes non-linear components. In FIG. 1, initial total charge 118 represents the initial total charge capacity or total volume of battery 100 at the time of manufacture. Battery 100 has a charged portion 114 and an uncharged portion 116. Uncharged portion 116 is charge-free, and may be so because battery 100 was not fully charged on a previous charge cycle, because charge has recently been supplied by battery 100, and/or for other reasons. As battery 100 ages, the performance of the cell(s) of battery 100 will degrade, creating an unusable portion 106. As indicated by arrows 108, the size of unusable portion 106 increases during the life of battery 100. Thus, unusable portion 106 represents a decrease over time in the amount of charge that battery 100 may store due to aging-related degradation.

A charge process equilibrium portion 110 of battery 100 is also shown in FIG. 1. Charge process equilibrium portion 110 represents an unknown state of battery 100 due mainly to the discharge rate of battery 100. As indicated by arrows 112 in FIG. 1, the charge volume of portion 110 may fluctuate. The charge volume of portion 110 depends on various parameters, such as the aging of battery 100, a state of charge of battery 100, a history of use of battery 100, a temperature of battery 100, etc. In portion 110, electrons are in transition after a charging or discharging event, but typically come to equilibrium after time (e.g., after 1 hour). A state of health (SOH) 120 of battery 100 is indicated in FIG. 1. SOH 120 represents a total charge capacity of battery 100, which is an amount of charge that may actually be available in battery 100, taking into account aging of battery 100. For instance, if battery 100 has an initial charge capacity of 130 mAH (milli-Ampere-hour) (initial total charge 118) that has decreased by 20%, SOH 120 of battery 110 may be calculated as SOH=130 mAH (100%-20%)=104 mAH. In this example, when fully charged, battery 100 is able to provide 104 mAH of charge, which is a reduction from the initial charge capacity of 130 mAH.

The status of battery 100 or the state of charge (SOC) 122 represents an amount of charge currently in battery 100 that can be used. SOC 122 is typically defined as a percentage. SOC 122 of battery 100 is conventionally determined according to a Coulomb counting approach. According to this approach, charging and/or discharging of battery 100 is monitored to determine the amount of charge entering or leaving battery 100. For example, FIG. 2 shows battery 100 during a charge or discharge period. During a discharge period, portion 202 of FIG. 2 may represent the amount of charge that leaves battery 100, decreasing the amount of charged portion 114. During a charge period, portion 202 of FIG. 2 may represent the amount of charge flowing into battery 100, increasing the amount of charged portion 114. This charge/discharge amount of portion 202 may be estimated according to

Q=I×T Equation 1

where

I=a current flowing into or out of battery 100 during time duration T.

SOC 122 may be calculated based on SOH 120, according to

SOC (%)=RC/SOH Equation 2

where

RC=remaining charge stored in battery 100.

RC may be calculated in various ways, including according to

RC=SOH−Q Equation 3

where Q is determined according to Equation 1 above, such that T is the time duration measured from last time when battery 100 was fully discharged/charged.

An electrical device that uses battery 100 for power may use the Coulomb counting approach to perform its battery fuel gauging. For instance, the device may use the Coulomb counting approach to determine SOC 122, determining that battery 100 is “42% full,” for example. To make this determination using the Coulomb counting approach, the electrical device must track SOH 120 for battery 100 (i.e., determining the capacity of battery 100, as well as potentially taking into account other factors). The electrical device typically may have a fuel gauging resistor and an analog to digital converter (AC) that track the charge current during the whole charging cycle, or may perform Coulomb counting in another manner.

### C. Example Embodiments Relating to Tracking Aging Effect on Battery Impedance

The example embodiments described herein are provided for illustrative purposes, and are not limiting. The examples described herein may be adapted to any type of electrical device. Furthermore, additional structural and operational embodiments, including modifications/alterations, will become apparent to persons skilled in the relevant art(s) from the teachings herein.

For reporting the status of a battery or the battery state of charge (SOC), one option is to rely on a battery voltage-based approach. Using a measured voltage and a battery impedance or equivalent series resistance (ESR) of the battery, it is possible to accurately estimate the state of charge. The impedance may be directly calculated or may be determined from an impedance table. One characteristic of the battery impedance is that it fluctuates along with many parameters, such as the state of charge, temperature, age, usage history, and number and type of charges/discharges. The effect of these parameters on battery impedance is not accounted for in the typical impedance table.

According to embodiments, the effect of aging on battery impedance may be taken into account to enable more accurate battery impedance values to be determined In embodiments, the effect of aging on battery impedance may be taken into account by monitoring known and reproducible state transitions of the battery, calculating the impedance at or after these known state transitions, and updating the impedance values in the impedance table used for the state of charge estimation. The accuracy of the state of charge estimation may be improved by using the updated impedance values that account for the effect of aging on the battery.

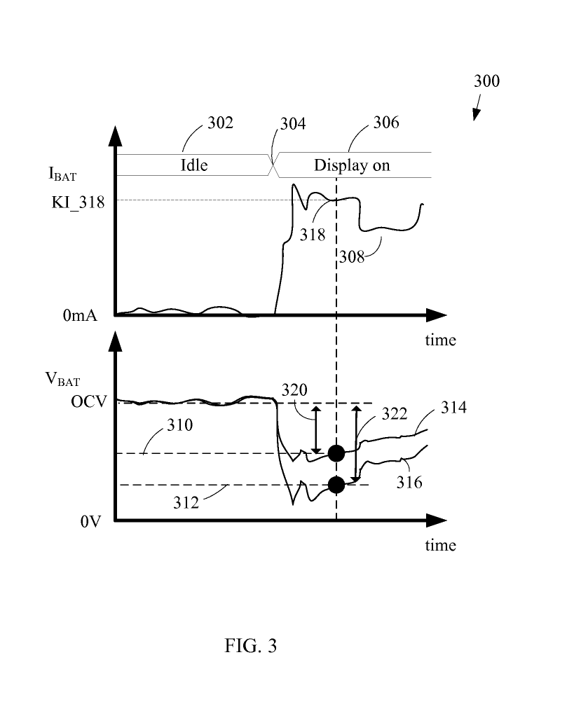

For example, FIG. 3 shows a graph 300 that includes waveforms illustrating the voltage and current of a battery over time, such as battery 100 shown in FIG. 1. In particular, FIG. 3 shows a voltage waveform 314 associated with a new battery, a voltage waveform 316 associated with an old battery, and a current waveform 308 during a transition 304 from an idle state 302 to an active state 306. Idle state 302 represents a state when the old and new batteries are at rest with little or no current flowing into or out of the batteries. Active state 306 represents a state during which the old and new batteries are active and current is flowing into or out of the batteries. Any number of activity may cause a transition from idle state 302 to active state 306, such as when a display of the device that includes the old/new battery is switched from an off to an on state.

A state of charge estimation of a battery may be more accurate when determined while the battery is in or near an idle state. During idle state 302, voltage waveform 314 and voltage waveform 316 are substantially constant and can be considered “open circuit voltages” of the new battery and the old battery, respectively. A battery may need to be in idle state 302 for a period of time (e.g., 30 minutes or an hour for the equilibrium portion 110 of battery 100 to settle) before a new impedance value can be accurately determined This period of time may be dependent on the voltage of the battery. For instance, this period of time may be shorter when the battery is full and may be longer when the battery is empty. However, the relationship between this period of time and the voltage of the battery may not always be linear. Generally, the longer the battery is in an idle state, the more accurate the calculations of the battery characteristics (e.g., impedance, state of health, etc.) may be.

Transition 304 indicates a change from one battery state to another, and in FIG. 3, transition 304 indicates a change from idle state 302 to active state 306. At transition 304, a voltage drop occurs that is representative of the battery impedance. For the new battery, transition 304 corresponds to voltage drop 320 in voltage waveform 314 to a voltage 310, and for the old battery, transition 304 corresponds to voltage drop 322 in voltage waveform 316 to a voltage 312. Voltage 310 or V_{BAT1} is shown that represents the voltage of the new battery at a particular point in time after transition 304 and at a known current 318 (e.g., 200 mA). Voltage 310 may be determined by the following equation

VBAT1=OCV−ESR_new_bat×KI_{—}318 Equation 4

where

OCV=open circuit voltage,

ESR_new_bat=impedance of new battery, and

KI_318=a known current during active state 306 for the battery.

Voltage 312 or VBAT2 represents the voltage of the old battery at that same time after transition 304 and at the same known current 318 (e.g., 200 mA). Voltage 312 may be determined by the following equation

VBAT2=OCV−ESR_old_bat×KI_{—}318 Equation 5

where

OCV=open circuit voltage,

ESR_old_bat=impedance of old battery, and

KI_318=a known current during active state 306 for the battery.

Even though the old battery and the new battery both experience the same (or similar) state transition 304, the voltage drop of the old battery is different from the voltage drop of the new battery, such that the voltage drop of the old battery is greater than the voltage drop of the new battery. This difference between the voltage drops is representative of the battery impedance evolution with age. Graph 300 of FIG. 3 shows that the impedance of a new battery is different from an old battery at the same known current consumption level (e.g., the impedance of the new battery is smaller than the impedance of the old battery in the example of FIG. 3). Thus, if the same impedance value is used for SOC calculations for batteries of different ages, as it would be with a typical impedance table that does not account for battery age, the results would be inaccurate. Thus, to obtain a more accurate battery state of charge, it is desirable to track and take into account the aging effect on battery impedance.

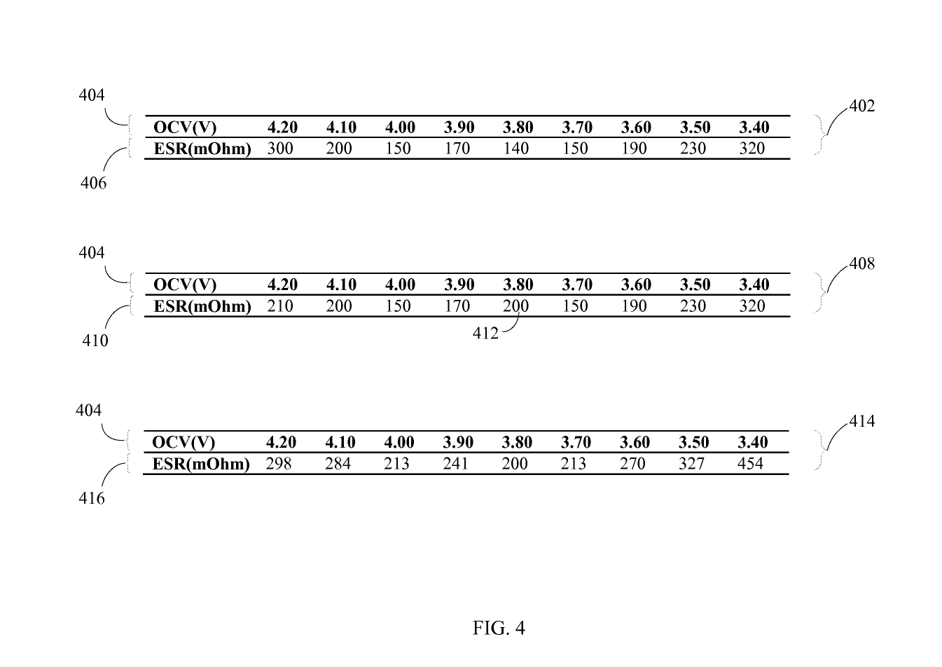

FIG. 4 shows three impedance tables 402, 408, and 414 that may be used for SOC estimation. Battery fuel gauging circuit/device manufacturers may provide an initial impedance table 402 that characterizes a battery or a type of battery. Table 402 may be stored in or is accessible to the fuel gauging circuit/device. Table 402 includes a first row 404 and a second row 406. Second row 406 includes ESR values as a function of battery voltage (OCV), which has values included in first row 404. Nine columns of ESR values and corresponding OCV values are shown in table 402 for purposes of illustration, although any number of ESR value-OCV value pairs may be present. Furthermore, table 402 may contain a different range of data, the same range of data at different discrete intervals, or a different type of data (e.g., ESR data as a function of the state of charge rather than the open circuit voltage). Alternatively, a single number (e.g., an average ESR value) may be provided rather than a table of values.

Table 408 includes first row 404 from table 402, and includes a second row 410 of ESR values. Table 408 is the same as table 402, other than second row 410 of table 408 including an updated impedance value 412 in a fifth column that is different from the corresponding impedance value in the fifth column of second row 406 of table 402.

Table 414 includes first row 404 from table 402, and includes a second row 416 of ESR values. Table 414 is the same as table 402, other than second row 416 of table 414 containing updated impedance values in all columns that are different from the corresponding impedance values in table 402.

Tables 408 and 414 both include one or more impedance values that were updated subsequently to table 402 being initially generated. Any of the impedance values may be determined and updated as time proceeds and the battery ages. Thus, in embodiments, any one or more impedance values in an impedance table may be updated over time as a battery ages, so that SOC calculations may be performed for the battery using more accurate impedance values, resulting in more accurate SOC values.

Updated impedance values may be determined in any manner. For instance, FIG.

5 shows a battery management system 500, according to an example embodiment. Battery management system 500 includes battery 100 and a battery manager 502. Battery manager 502 is coupled to battery 100 by an electrical connection 504, and is configured to determine the impedance and/or the SOC 122 of FIG. 1 for battery 100. FIG. 6 shows a flowchart 600 providing example steps for determining a state of charge of a battery according to an example embodiment. For example, battery management system 500 may perform flowchart 600 in an embodiment. Other structural and operational embodiments will be apparent to persons skilled in the relevant art(s) based on the discussion regarding flowchart 600. Flowchart 600 is described as follows.

Flowchart 600 begins with step 602. In step 602, a first voltage of a battery associated with a first state of the battery is determined For example, in an embodiment, an initial voltage (e.g., a data point of voltage waveform 314 or voltage waveform 316 of FIG. 3) of a new/old battery, such as battery 100, is determined during idle state 302. This initial voltage is close to an open circuit voltage and may be considered as such for purposes of battery state of charge calculations. The initial voltage may be measured in any manner, as would be known to persons skilled in the relevant art(s).

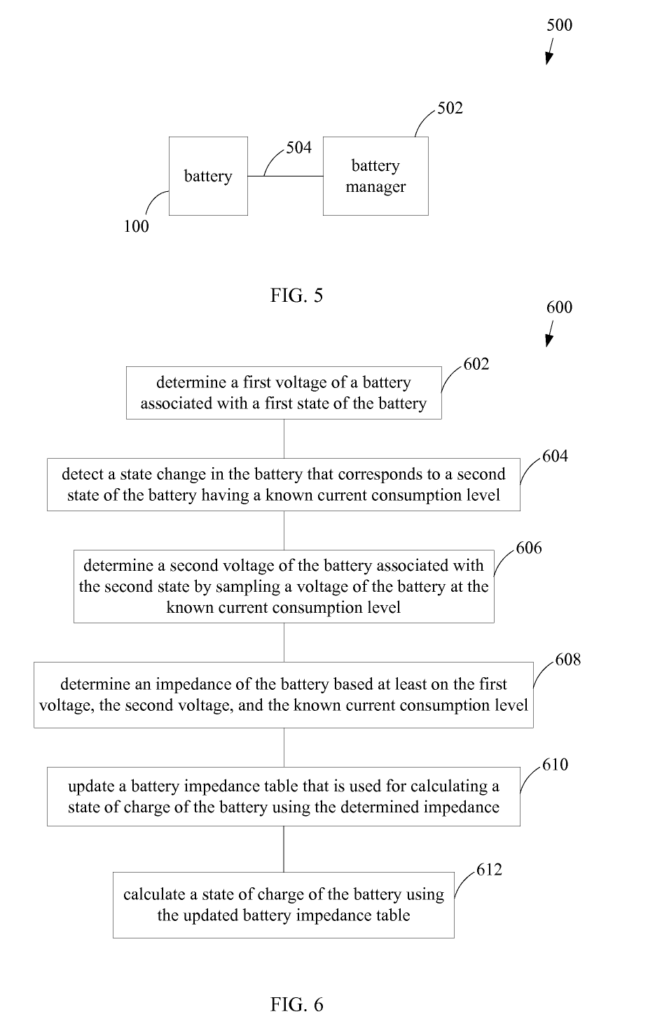

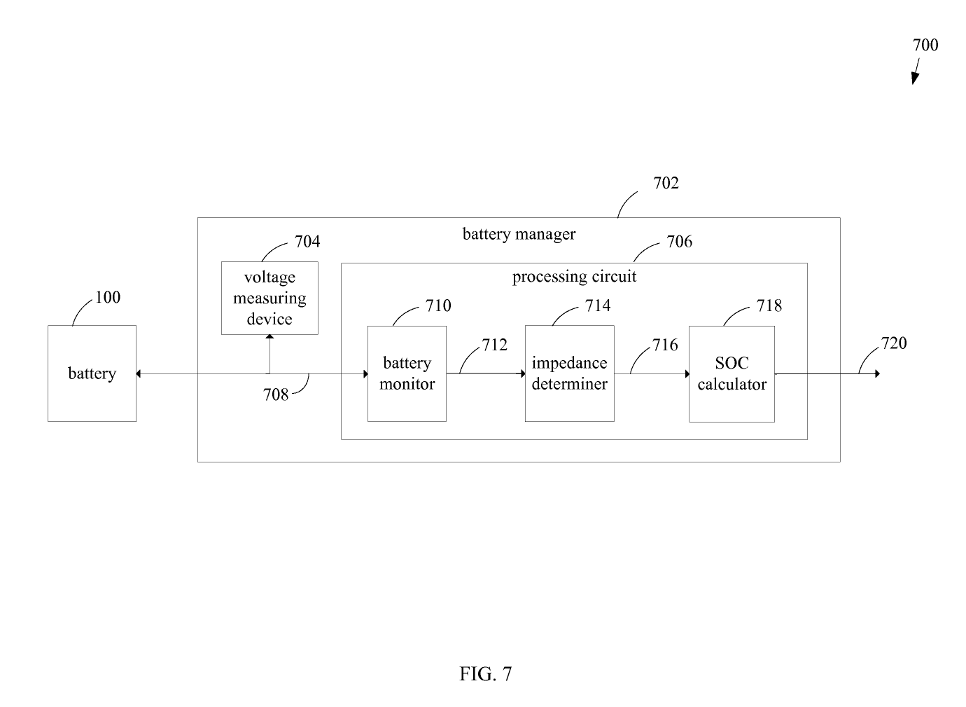

For instance, FIG. 7 shows a battery management system 700, as an example of battery management system 502 in FIG. 5, according to an embodiment. As shown in FIG. 7, battery management system 700 includes battery 100 and battery manager 702, which are coupled together by electrical connection 708. In the embodiment of FIG. 7, battery manager 702 includes a voltage measuring device 704 and a processing circuit 706. Furthermore, processing circuit 706 includes a battery monitor 710, an impedance determiner 714, and a SOC calculator 718. Voltage measuring device 704 may be configured to perform step 602 of flowchart 600. Voltage measuring device 704 may be configured to measure the voltages of battery 100 at different states, including idle state 302 shown in FIG. 3, for example. Voltage measuring device 704 may be implemented by any suitable type of voltage measuring device, including a commercially available voltage measuring device or a proprietary one.

In an embodiment, battery 100 is monitored in idle state 302 for a period of time before voltage measuring device 704 measures the voltage of the battery. This period of time may be dependent on various factors, including a charge level of the battery (i.e., the state of charge) and an accuracy of the battery fuel gauging mechanism. For example, if the electrical device that includes battery 100 is a mobile phone, then the mobile phone may need to be at rest or in scan mode for some time (e.g., 30 minutes) before the voltage associated with this idle state is determined as, for example, V_{BAT}_{_{—}}_{NIT}=3.80 V.

In step 604, a state change in the battery that corresponds to a second state of the battery having a known current consumption level is detected. In an embodiment, battery manager 702 shown in FIG. 7 may be configured to detect a state change in the battery corresponding to a state of the battery having a known current consumption level. For example, battery monitor 710 of battery manager 702 may be configured to perform step 604. As shown in FIG. 7, processing circuit 706 is electrically coupled to battery 100 and voltage measuring device 704 via electrical connection 708. Battery monitor 710 may be configured to detect a state change, from idle state 302 to active state 306 as shown in FIG. 3, for example. Battery monitor 710 is configured to determine that the new state has a known current consumption level (e.g., KI_318) associated with active state 306, which may be a stored value for a particular function of the device (e.g., a current value used when the display is on, when music is playing, etc.) or may be a value measured by battery monitor 710. Battery monitor 710 may be configured to determine that a state change has occurred by detecting the occurrence of transition 304 (e.g., determining that a particular function has been activated, etc.) and transmitting a signal to instruct voltage measuring device 704 to measure a battery voltage at the known current consumption level. Battery monitor 710 may include any type of monitoring mechanism to determine the change in state of battery 100. For example, battery monitor 706 may include analog or digital logic configured to monitor battery 100, and may be implemented in a processor.

To continue with the above example, when a user activates the mobile phone by turning on the display, as shown in FIG. 3, a state change occurs and this transition may be detected. This state change is predictable in the sense that the current consumption is predictable or known. For instance, battery monitor 710 may be configured to determine that the new state has a known current consumption level of 200 mA associated with active state 306.

In step 606, a second voltage of the battery associated with the second state is determined by performing a voltage sampling of the battery at the known current consumption level. In an embodiment, battery manager 702 may be configured to determine a second voltage of the battery in a manner similar to how the first voltage of the battery is determined in step 602. For instance, in an embodiment, voltage measuring device 704 may be configured to determine the voltage of active state 306 from a voltage sampling of battery 100 at known current 318 as shown in FIG. 3.

To continue with the above example, the second voltage of the battery associated with the active state may be determined by sampling the battery voltage at known current I_{BAT}=200 mA to be V_{BAT}_{_{—}}_{ON}=3.76 V.

In step 608, an impedance of the battery is determined based at least on the first voltage, the second voltage, and the known current consumption level. In an embodiment, battery manager 702, shown in FIG. 7, may be configured to determine the impedance of battery 100 based on the first voltage associated with idle state 302, the second voltage associated with active state 306, and known current 318 (for the active state) shown in FIG. 3.

For example, as shown in FIG. 7, impedance determiner 714 is electrically coupled to battery monitor 710 by electrical connection 712. Impedance determiner 714 is configured to receive parameters determined in steps 602-606, such as the voltages of the idle and active states of battery 100 and known current level 318 from battery monitor 710 and/or other components. Impedance determiner 714 is further configured to use the obtained parameters to calculate the battery impedance. For instance, impedance determiner 714 may calculate a difference between the idle and active state voltages, and may divide the difference by the determined current level, as indicated in Equation 6 below:

ESR(OCV)=(V_{BAT}_{_{—}}_{INIT}−V_{BAT}_{_{—}}_{ON})/I_{BAT} Equation 6

where

V_{BAT}_{_{—}}_{NTT}=initial voltage/open circuit voltage,

V_{BAT}_{_{—}}_{ON}=transition/active state voltage, and

I_{BAT}=known or predictable current.

Impedance determiner 714 may include any mechanism, such as analog and/or digital logic configured as an impedance determiner, to determine the impedance. Impedance determiner 714 may be implemented in a processor and/or may include any other mechanism to determine the battery impedance (e.g., an Ohmmeter, etc.). Impedance determiner 714 and/or processing circuit 706 may be implemented as separate devices/circuits used for fuel gauging purposes or may alternatively be integrated into the circuitry of the electrical device that includes battery 100. For instance, impedance determiner 714 may be integrated into the processing circuitry/processor of a mobile telephone.

To continue with the above example, the impedance of battery 100 may be determined based on Equation 6. Applying the values from the above example to Equation 6, the impedance of battery at 200 mA is equal to (3.8 V−3.76 V)/0.2 A=200 mOhm.

In step 610, a battery impedance table that is used for calculating a stage of charge of the battery is updated with the determined impedance. Battery manager 702, shown in FIG. 7, is configured to update a battery impedance table, such as table 402 of FIG. 4. For example, in an embodiment, impedance determiner 714 is further configured to update table 402 with an updated impedance value that was calculated in step 608. As shown in FIG. 4, the newly determined battery impedance or updated impedance value 412 (200 mOhm) from the above example may be used to update impedance table 402, resulting in table 408. Updated impedance value 412 of “200 mOhm” corresponding to the OCV of 3.8 V, is used to replace the initial impedance value of “140 mOhm” corresponding to the same OCV in the fifth column of table 402. Depending on battery characteristics and the occurrence of the recalibration events associated with these characteristics, the entire table may be updated rather than just a single value. For example, as shown in FIG. 4, table 414 is table 402 with all new, updated impedance values shown in second row 416.

Updated impedance value 412 may be directly substituted for an original impedance value as set forth in the example above. Alternatively, updated impedance value 412 may be manipulated or further processed in some way before it is used to update impedance table 402. In embodiments, updated impedance value 412 may be filtered, may be averaged with other impedance values, may be an interpolated value between a pair of calculated values (e.g., when a column of the measured voltage is not present in table 402), and/or may be used for determining confidence of a steady state (e.g., used to determine or confirm whether a battery steady or equilibrium state has been reached).

In step 612, a state of charge of the battery using the updated battery impedance table is calculated. For example, in an embodiment, the state of charge may be calculated using an entry of table 408 or table 414 of FIG. 4, both of which contain updated impedance value(s). In an embodiment, Equation 7, shown below, may be used to estimate the state of charge as a function of the open circuit voltage (OCV):

SOC=f(OCV)=f(V_{BAT}+ESR(OCV)×I_{BAT}). Equation 7

where

V_{BAT}=measured voltage,

ESR(OCV)=impedance as a function of the open circuit voltage, and

I_{BAT}=current flowing into or out of battery.

The state of charge may be determined in this manner, or any other manner, as would be known to persons skilled in the relevant art(s). For instance, SOC calculator 718 shown in FIG. 7 may be configured to determine the state of charge of battery 100 according to Equation 7. As shown in FIG. 7, SOC calculator 718 is coupled to impedance determiner 714 by electrical connection 716. In an embodiment, impedance determiner 714 may maintain and/or have access to the impedance table(s). As such, SOC calculator 718 may receive an impedance value of an impedance table from impedance determiner 714 over electrical connection 716. SOC calculator 718 may be configured to perform step 612 by using the received impedance value in Equation 7 (or other suitable equation) to determine a battery state of charge 720.

Processing circuit 706, including battery monitor 710, impedance determiner 714, and SOC calculator 718, may be implemented in hardware, or a combination of hardware with software and/or firmware. For example, in an embodiment, processing circuit 706 may include one or more processors, and battery monitor 710, impedance determiner 714, and SOC calculator 718 may be implemented as code/instructions stored in a computer readable storage medium (e.g., a memory device, a magnetic disc, an optical disc such as a compact disc read only memory (CDROM), or other storage device) that is executed by the one or more processors. In another example embodiment, processing circuit 706 may include hardware logic (e.g., an ASIC, logic gates, etc.) configured to perform the functions of battery monitor 710, impedance determiner 714, and SOC calculator 718, and may include memory to store data. Processing circuit 706 may include an analog to digital converter (ADC) to convert a measured analog current value to digital form, and/or to perform other analog to digital conversions if necessary. Alternatively, processing circuit 706 may be configured to use an estimate of current values, rather than being configured to convert analog current values to digital form.

### D. Example Embodiments Relating to Tracking Battery State of Health Based on Charging Step Occurrences

Correct estimation of the state of health of a rechargeable battery is important for an accurate estimation of a battery status, or its state of charge. Indeed, when the state of charge estimation is based on the Coulomb counting method of counting the charges flowing into or out of the battery, the state of charge may be determined based on the SOH according to the following equation:

SOC (as a percent)=SOC (in Coulomb)/SOH (in Coulomb) Equation 8

During the counting process, a voltage limit (e.g., around 3.4 V for a lithium battery) may be deemed the “battery empty” event or state. Charges may be counted while the battery is charged from this empty battery state until a full battery state is reached or charges may be counted while the battery is discharged from the full battery state to the empty battery state to obtain a number of cumulated charges. The cumulated charges may also be calculated using Equation 1 set forth in section B above (e.g., measuring the current flow into the battery, and integrating the measured current over time). The cumulative charges may be used to estimate the state of health of a battery as it may be difficult or impractical to calculate the state of health in a more accurate manner due to the complex chemistry of a battery. As a battery ages, the charge capacity decreases, and it is useful to track this changing charge capacity, as otherwise it is difficult to know when the battery full event or the battery empty event has been reached while counting charges. Thus, it is useful to track the charge capacity or the state of health (SOH) of the battery.

As portable devices are used to store more and more important information and perform more and more functions, the users of these devices tend to avoid completely draining the rechargeable batteries. Thus the battery empty event and to some extent, the battery full event, rarely occur in the life of these batteries. Rather, these batteries may be recharged before they are completely empty (by partial charges) and/or they may be discharged before they are fully charged (by partial discharges). Accordingly, batteries may experience multiple partial charge cycles and partial discharge cycles between a battery empty event and a battery full event. The partial charging and partial discharging of a battery may cause errors in the cumulated charge estimation (e.g., error measurements due to analog to digital converter reading, misestimating a device sleep period, etc.). Some of these errors, such as the sleep period misestimation, are asymmetric, thereby causing the estimated state of health to diverge from the actual state of health of the battery.

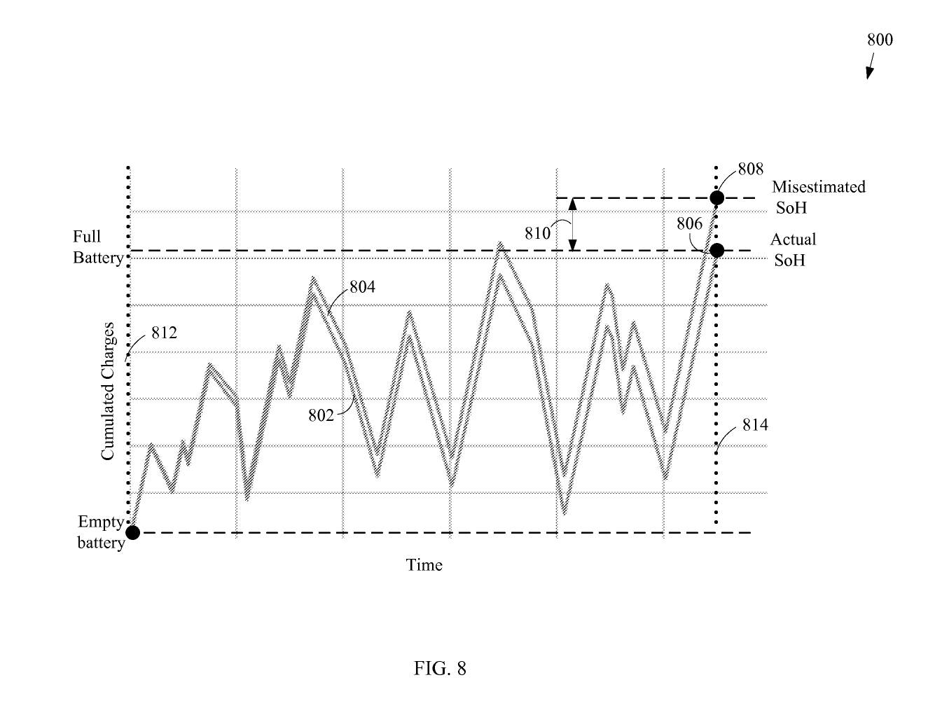

For instance, FIG. 8 shows a graph 800 illustrating the divergence of the estimated state of health from the actual state of health of a battery, such as battery 100 of FIG. 1. Graph 800 shows a first waveform 802 and a second waveform 804. First waveform 802 represents an example of actual cumulated charges from a battery empty event at a time 812 to a battery full event at a time 814. Second waveform 804 represents the estimated cumulated charges of the same battery over the same period of time. As shown by waveform 802, the battery may go through a large number of partial charge-partial discharge cycles between a battery empty event and a battery full event. Due to the many cycles, the estimated value of the cumulative charges stored in the battery gradually diverges from the actual value of the cumulative charges stored in the battery. At the battery full event at time 814, an estimated state of health value 808 is indicated on waveform 804. Estimated SOH value 808 is an inaccurate SOH value because it has diverged from the actual state of health value 806 on waveform 802 by an error amount 810. Error amount 810 is an accumulation error resulting from the cumulated partial charges.

According to embodiments, to prevent a battery SOH value from being determined that includes a significant value for error amount 810, cumulative charging charge being applied to a battery may be tracked beginning at a battery empty event (or a battery full event). The cumulative charging charge takes into account charges entering the battery during partial charging cycles, and does not count the charges leaving the battery during partial discharging cycles. The cumulative charging charge may be tracked subsequent to this time to monitor the cumulated amount of charge flowing into the battery during partial charges events that occur. The cumulative charging charge may be compared with a predetermined threshold value that may be equivalent to a selected number of one or more full charge cycles. If the tracked cumulative charging charge reaches the predetermined threshold value, the tracked cumulative charging charge may not be used to determine a new SOH estimation because it may be deemed to be erroneous. However, when a battery full event is reached (or a battery empty event), and if the tracked cumulative charging charge is less than the predetermined threshold value, the tracked cumulative charging charge may be used to determine a new SOH estimation. For instance, Coulomb counting from the battery empty event to the battery full event may be used to generate a new estimated value for SOH, or a new value for SOH may be estimated in another manner.

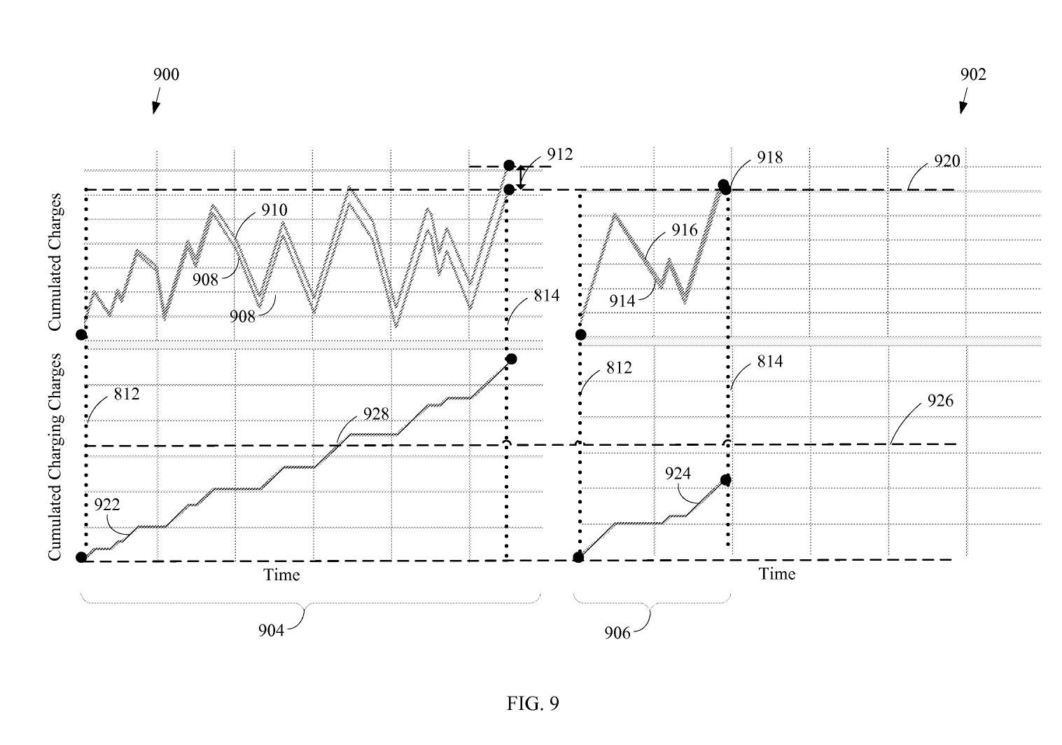

For example, FIG. 9 shows a graph 900 illustrating a case where the cumulated charging charges may not be used for state of health estimation, and shows a graph 902 illustrating a case where the cumulated charging charges may be used for state of health estimation, according to an example embodiment. Graph 900 includes a first waveform 908 and a second waveform 910, which are generally similar to waveforms 802 and 804 shown in FIG. 8. As shown in graph 900, waveforms 908 and 910 indicate cumulated charges versus time, beginning at time 812 (a discharged battery state), taking into account both partial charging and partial discharging cycles. Waveform 908 represents the actual cumulated charges for a battery and waveform 910 represents the estimated cumulated charges for the battery after time 812. Error 912 represents the error between the actual and estimated cumulated charges at a battery full event 920 (at time 814 in graph 900). Waveform 908 shows that the battery in this case has been partially charged and partial discharged numerous times before reaching battery full event 920. Because of the many partial charges and discharges, the time it takes to reach battery full event 920, indicated as a time period from time 812 to time 814 may be long. The number of partial charge-discharge cycles may cause an increasing difference between the actual and estimated cumulated charges, leading to error 912 at battery full event 920.

Graph 900 also shows a waveform 922 that indicates cumulated charging charges versus time, beginning at time 812. Waveform 922 may represent cumulative charging charges, where a cumulative amount of charge stored in the battery is tracked after time 812 without taking into account any discharges of the battery since time 812. Threshold 926 is a predetermined threshold representing an amount of cumulative charging charge stored in the battery. When the value of the cumulated charging charges in waveform 922 exceeds the value of threshold 926, there is high risk of divergence error due to partial charges. As such, an inaccurate value for SOH may be generated, and the value of the SOH may not be accurate enough to be used to calculate SOC. Thus, predetermined threshold 926 represents a cut-off point of usable tracked cumulative charging charge data. Threshold 926 may be predetermined by a user or device. For example, predetermined threshold 926 may be set to a number, such as the charge value of a partial charge cycle, one full charge cycle (e.g., the current value of SOH), two full charge cycles, other multiples of a full and/or partial charge cycle, or to another value. In other words, in an embodiment, an amount of cumulative charging charge may be tracked/counted until an equivalent of one full charge cycle, two full charge cycles, or other value for threshold 926 is reached. If the amount of the cumulative charging charge is greater than or equal to threshold 926, it may be assumed that the divergence error has become too great, and as such, it may be desirable to not use data collected to calculate SOH or SOC.

Note that a value for predetermined threshold 926 may be dependent on the accuracy of the system used to track the state of health of the battery. There is inherently less risk of divergence associated with an accurate tracking system, such as a tracking system with a precise current measurement device and/or time measurement device. The tracking system may be implemented in a battery manager, such as battery manager 502 shown in FIG. 5. For a tracking system that is fairly accurate, predetermined threshold 926 may be set at a higher number (e.g., more than two charge cycles) than for a tracking system that is not as accurate.

Referring back to graph 900 of FIG. 9, if predetermined threshold 926 is set at two full charge cycles, then waveform 922 reaches the amount of cumulative charging charge that is equivalent to two full charge cycles at a time 904. Thus, by the time battery full event 926 occurs in graph 900, predetermined threshold 926 has previously been exceeded. Thus, cumulated charging charges of waveform 922 may not be used for state of health estimation for the battery in this case.

As shown in FIG. 9, graph 902 includes a first waveform 914 and a second waveform 916, which are generally similar to waveforms 802 and 804 shown in FIG. 8. As shown in graph 902, waveforms 914 and 916 indicate cumulated charges versus time, beginning with a battery empty event at time 812. Waveform 914 represents the actual cumulated charges and waveform 916 represents the estimated cumulated charges. As depicted in graph 902, waveform 916 has not diverged much from waveform 914. As such, the estimated charges are close to the actual charges, as desired. As shown in graph 902, the amount of divergence error 918 between waveforms 914 and 916 is quite small. Because the battery in this case has undergone only a few partial charges, the time taken to reach battery full event 920, indicated as the time period from time 812 to a time 906 may be relatively short—shorter than the time it would take for a battery having undergone more partial charges before reaching a battery full event.

Graph 902 also shows a waveform 924 that indicates cumulated charging charges versus time. Waveform 924 may represent tracked cumulative charging charge data. In an example embodiment, if predetermined threshold 926 is set to two full charge cycles, then waveform 924 reaches an amount of cumulative charging charge that is less than two full charge cycles at battery full event 920, which is shown occurring at time 906. In other words, for the battery of graph 902, predetermined threshold 926 has not been reached at battery full event 920. Thus, cumulated charging charges of waveform 924 may be used for a new state of health estimation for the battery in this case.

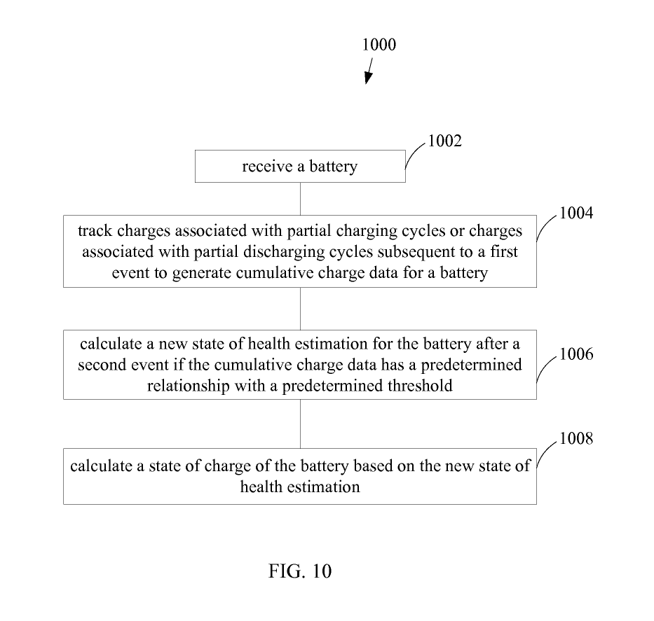

Cumulative charging or discharging charge data may be tracked in any manner in example embodiments. For instance, FIG. 10 is a flowchart 1000 providing a process for tracking battery state of health, according to an example embodiment. Flowchart 1000 may be performed by battery management system 502 shown in FIG. 5. Other structural and operation embodiments will be apparent to persons skilled in the relevant art(s) based on the discussion regarding flowchart 1000. Flowchart 1000 is described as follows.

Flowchart 1000 begins with step 1002. In step 1002, a battery is received. For example, in an embodiment, battery 100 is received in battery management system 1100. Received battery 100 may be charged or substantially uncharged. For example, in an embodiment, battery 100 is received with charged portion 114 substantially empty of charge (i.e., battery 100 is uncharged). In another example, battery 100 may be received fully charged.

In step 1004, charges associated with partial charging cycles or charges associated with partial discharging cycles are tracked subsequent to a first event to generate cumulative charge data for the battery. As described above, in an embodiment, cumulative charging charges applied to a battery may be tracked after a first event, which may be an empty battery event. In such an embodiment, the tracking of the cumulative charging charges may include counting charges entering the battery during partial charging cycles while the charges leaving the battery during partial discharging cycles are not counted. In another example embodiment, cumulative discharging charges leaving a battery may be tracked after a first event, such as a battery full event. In this embodiment, the tracking of the cumulative discharging charges may include counting charges leaving the battery during partial discharging cycles while the charges entering the battery during partial charging cycles are not counted.

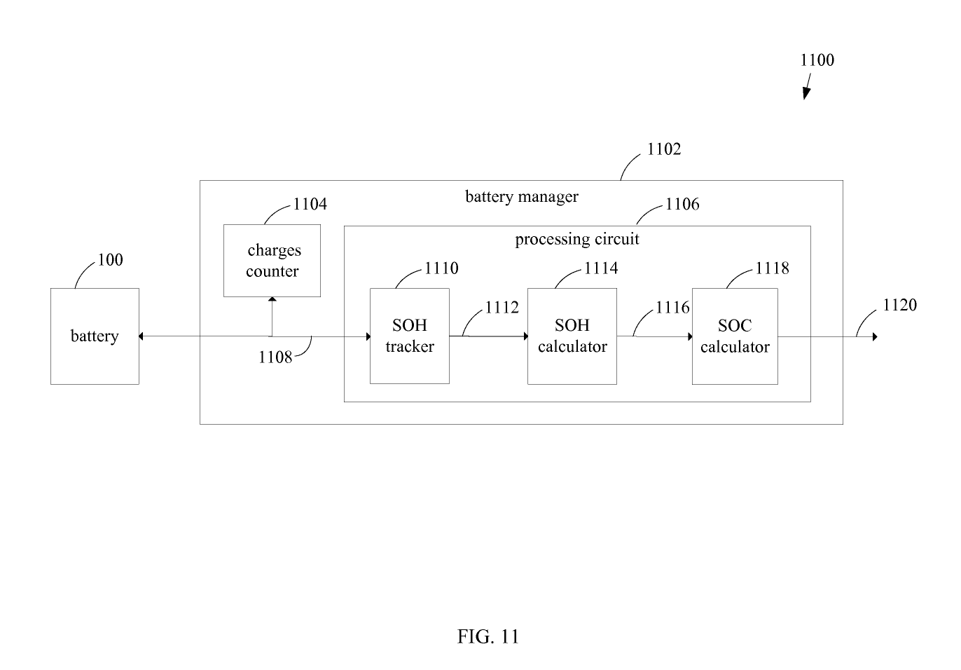

Step 1004 of flowchart 1100 may be implemented in various manners. For example, FIG. 11 shows a battery management system 1100, as an example of battery management system 502 in FIG. 5, according to an embodiment. As shown in FIG. 11, battery management system 1100 includes a battery 100 and battery manager 1102, which are coupled together by electrical connection 1108. Battery manager 1102 includes a charges counter 1104 and a processing circuit 1106, which are also coupled together by electrical connection 1108. Processing circuit 1106 includes a SOH tracker 1110, a SOH calculator 1114, and a SOC calculator 1118. Charges counter 1104 may be configured to track (e.g., count) the partial charging charges provided to battery 100 between a battery empty event and a battery full event, and/or may be configured to track the partial discharging charges leaving battery 100 between a battery full event and a battery empty event. Charges counter 1104 may be implemented by any type of charge counting counter, including a commercially available charge counter or a proprietary charge counter. For instance, charges counter 1104 may be configured to perform Coulomb counting, such as by including a fuel gauging mechanism described elsewhere herein or otherwise known. In an embodiment, SOH tracker 1110 shown in FIG. 11 may track (e.g., store) the counted charges by receiving indications of counted charges from charges counter 1104 over electrical connection 1108. The tracked charge data may be cumulated and maintained by SOH tracker 1110 as cumulative charge data that includes cumulative charging charges or cumulative discharging charges, depending on the particular embodiment. The cumulative charge data may be plotted in a similar manner to waveform 922 in FIG. 9, for example.

In step 1006, a new state of health estimation is calculated for the battery after a second event if the cumulative charge data has a predetermined relationship with a predetermined threshold. For instance, in an embodiment, battery manager 1102 of FIG. 11 may be configured to calculate a new state of health estimation for the battery if a second event is reached (e.g., a battery full event) and if the cumulative charging charge data tracked for battery 100 has a predetermined relationship with predetermined threshold 926, as shown in FIG. 9.

For example, as shown in FIG. 11, in an embodiment, SOH calculator 1114 may perform step 1006. As shown in FIG. 11, SOH calculator 1114 is coupled to SOH tracker 1110 by electrical connection 1112. As such, SOH calculator 1114 may receive cumulative charge data (e.g., cumulative charging charges or cumulative discharging charges) over electrical connection 1112. SOH calculator 1114 may utilize an algorithm or equation, such as Equation 1, to calculate the new SOH estimation based on the cumulative charge data associated with battery 100 that is tracked by SOH tracker 1110. In an embodiment, charges counter 1104 may determine that the second event has occurred, which is a battery full event if cumulative charging charges are being tracked (since a battery empty event), or which is a battery empty event if cumulative discharging charges are being tracked (since a battery full event). When such an event is detected, SOH calculator 1114 may determine whether the cumulative charge data has a value that is less than predetermined threshold 926, which may be set to be an equivalent of two full charge cycles or other value. If the cumulative charge data has a value that does not exceed predetermined threshold 926, a new state of health estimation may be performed (e.g., as a cumulative amount of change in the battery charge between the first event and the second event). Otherwise, the tracked cumulative charge of battery 100 is not used to calculate a new state of health estimation (e.g., the tracked cumulative charge data may be discarded).

In an embodiment, the new state of health estimation may be used to calculate a new state of charge of a battery. In another embodiment, the new state of health estimation may be averaged by an averaging function with one or more previously determined state of health estimations for the battery to generate an averaged state of health estimation. The averaged state of health estimation may be used to calculate a new state of charge for the battery. Other functions (e.g., filtering, sorting, interpolating) may optionally be used to manipulate the cumulative charge data in the process of calculating the new state of health estimation. Alternatively or additionally, SOH calculator 116 may be configured to determine a confidence level with respect to the new SOH estimation. For example, SOH calculator 1114 may balance/determine the importance of an SOH estimation based on the tracked cumulative charging charges.

Depending on the predetermined relationship (e.g., less than or equal to, greater than or equal to, equal to, etc.), predetermined count threshold 926 may have different values, and may be used differently to determine whether to use or discard cumulative charge data (until a new initial charge state, such as a discharged state, is reached).

Referring back to flowchart 1000, in step 1008, a state of charge of the battery is calculated based on the new state of health estimation. For example, SOC calculator 1118 shown in FIG. 11 may perform step 1008. As shown in FIG. 11, SOC calculator 1118 is coupled to SOH calculator 1114 via electrical connection 1116, and thus may receive the new SOH estimation from SOH calculator 1114 over electrical connection 1116. SOC calculator 1118 may include any type of analog or digital mechanism that may utilize an algorithm or equation, such as Equation 8, to calculate the state of charge of battery 100 based on the new SOH estimation. SOC calculator 1118 may output the calculated state of charge as SOC 1120, as shown in FIG. 11.

Processing circuit 1106, including SOH tracker 1110, SOH calculator 1114 and SOC calculator 1118 may be implemented in hardware, or a combination of hardware with software and/or firmware. For example, in an embodiment, processing circuit 1106 may include one or more processors, and SOH tracker 1110, SOH calculator 1114 and SOC calculator 1118 may be implemented as code/instructions stored in a computer readable storage medium that is executed by the one or more processors. In another example embodiment, processing circuit 1106 may include hardware logic (e.g., an ASIC, logic gates, etc.) configured to perform the functions of SOH tracker 1110, SOH calculator 1114, and SOC calculator 1118, and may include memory to store data. Processing circuit 1106 may include an analog to digital converter (ADC) to convert a measured analog current value to digital form, and/or to perform other analog to digital conversions if necessary. Alternatively, processing circuit 1106 may be configured to use an estimate of current values rather than being configured to convert analog current values to digital form.

### E. Other Example Embodiments

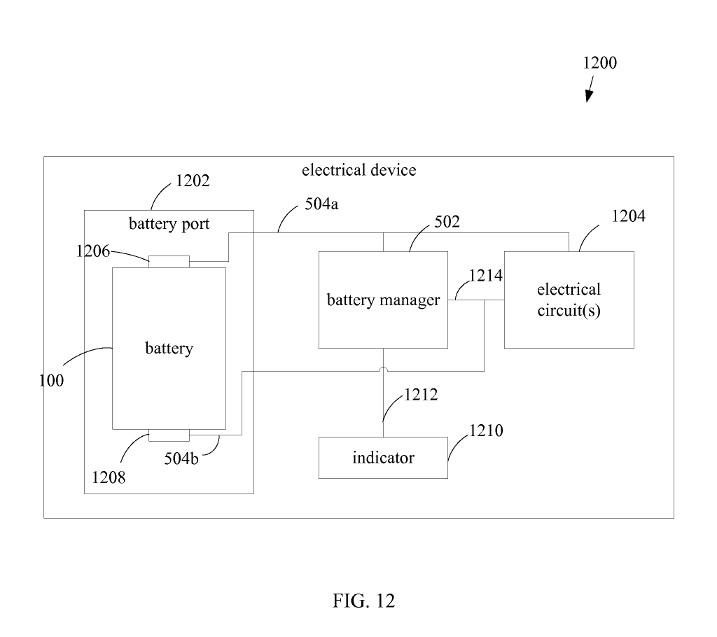

Battery manager 502 shown in FIG. 5 may be implemented in any type of electronic/electrical device that includes one or more rechargeable batteries. For example, FIG. 12 shows a block diagram of an example electrical device 1200 that incorporates battery manager 502, according to an embodiment of the present invention. As shown in FIG. 12, electrical device 1200 includes a battery port 1202, electrical circuit(s) 1204, and battery manager 502. Battery port 1202 is any type of battery port, including a recessed area, slot, or other opening configured to receive battery 100. In the example of FIG. 12, battery port 1202 includes a first contact 1206 and a second contact 1208. A first terminal of battery 100 (e.g., terminal 102 or terminal 104 shown in FIG. 1) makes contact with first contact 1206, and a second terminal of battery 100 makes contact with second contact 1208. First and second contacts 1206 and 1208 are respectively electrically coupled by first and second electrical connections 504a and 504b to battery manager 502 to provide a path for electrical current to battery manager 502 (and to electrical circuit(s) 1204 through battery manager 502).

In an embodiment, battery manager 502 may process a voltage received across first and second electrical connections 504a and 504b from battery 100 to generate a voltage signal that is output on a third electrical connection 1214. For instance, battery manager 502 may filter the received voltage, may set the output voltage signal to a predetermined voltage value (e.g., using a voltage regulator), and/or may otherwise process the received voltage. Second electrical connection 504b (e.g., a ground signal) and third electrical connection 1214 (e.g., a power signal) are received by electrical circuit(s) 1204, to provide power to electrical circuit(s) 1204 from battery 100.

Electrical connections 504a, 504b, and 1214 may each include one or more electrically conductive connections, such as wires, cables, connectors, metal strips, etc. as would be known to person skilled in the relevant art(s). First and second contacts 1206 and 1208 may be any type of contacts, conventional or otherwise, including metal contacts, as would be known to persons skilled in the relevant art(s). Note that the particular configuration for electrical device 1200 shown in FIG. 12 is provided for purposes of illustration, and that electrical device 1200 may be configured in alternative ways, as would be known to persons skilled in the relevant art(s).

Electrical device 1200 may be any sort of electrical device that uses electrical power, and that includes one or more batteries. For example, electrical device 1200 may be a stationary device or a portable device. Example devices for electrical device 1200 include mobile computers (e.g., a Palm® device, a laptop computer, a notebook computer, a netbook, a table computer, etc.), a personal digital assistant (PDA), a Blackberry® device), mobile phone (e.g., a cell phone, a smart phone, etc.), a handheld media player such as a handheld music/video player (e.g., a Microsoft Zune™ device, an Apple iPod™ device, etc.), a handheld game console (e.g., a Nintendo DS™, a PlayStation Portable™, etc.), a wireless headset (e.g., a Bluetooth® headset), a personal navigation device (e.g., a handheld global positioning system (GPS) device), a handheld digital video camera, and any other electrical device. Electrical circuit(s) 1204 may include any number of one or more electrical circuits providing functionality for electrical device 800, including computing/processing circuits, logic circuits, electromechanical circuits, video circuits, audio circuits, communications circuits, image capturing circuits, etc.

Electrical device 1200 may optionally include an indicator 1210, as shown in FIG. 12. Indicator 1210 is configured as indicator to provide an indication of the calculated state of health and/or state of charge of battery 100. Indicator 1210 receives a battery health information signal 1212 (such as state of charge 720 of FIG. 7 or state of charge 1120 of FIG. 11) from battery manager 502, which may include the calculated state of health and/or state of charge of battery 100. As shown in FIG. 12, indicator 1210 may display or otherwise output a state of health calculated by SOH calculator 1114 and/or a state of charge calculated by SOC calculators 718 and/or 1118. Indicator 1210 may be implemented in any manner to provide an indication of the calculated state of health and/or state of charge of battery 100. For example, indicator 1210 may include one or more light emitting diodes (LED), may include a textual readout and/or a graphical icon displayed by a display of electrical device 1200, and/or may include any other visual and/or audio output device of electrical device 1200. In an embodiment where indicator 1210 includes one or more LEDs, a color, an intensity, a number of illuminated LEDs, and/or any other configuration of the LEDs may be used to indicate a calculated state of health and/or state of charge of battery 100. In an embodiment where indicator 1210 includes a textual readout, the textual readout can display the state of health and/or the state of charge as actual values, as percentages representative of the state of health and/or state of charge, as an indicated amount of time remaining (e.g., “1 hour remaining”), and/or according to any other textual indication. In an embodiment where indicator 1210 includes a graphical icon, the graphical icon may indicate the state of health and/or the state of charge of battery 100 in any manner, such as by showing a partial battery icon, etc.

In another embodiment, indicator 1210 may be located in a second device that is separate from electrical device 1200. Electrical device 1200 may include a transmitter or other interface for transmitting the state of health and/or the state of charge output by battery manager 502 to the second device. For instance, in an embodiment, electrical device 1200 may be a headset powered by battery 100, and the second device may be a telephone (e.g., a portable phone, such as a cell phone). The headset may transmit the state of health and/or the state of charge information for battery 100 to the telephone. Indicator 1210 may be display on the telephone, which may display the state of health and/or the state of charge of battery 100 received from electrical device 1200.

### F. Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A method for tracking aging effect on battery impedance, comprising:
determining a first voltage of a battery associated with a first state of the battery;
detecting a state change in the battery that corresponds to a second state of the battery having a known current consumption level;
determining a second voltage of the battery associated with the second state by sampling a voltage of the battery at the known current consumption level;
determining an impedance of the battery based at least on the first voltage, the second voltage, and the known current consumption level; and
updating a battery impedance table that is used for calculating a state of charge of the battery using the determined impedance.

2. The method of claim 1, further comprising:
monitoring the battery in the first state for a period of time prior to said determining the first voltage of the battery, the period of time being dependent on a charge level of the battery.

3. The method of claim 1, wherein the battery is a lithium battery.

4. The method of claim 1, wherein the first state comprises an idle state of the battery.

5. The method of claim 1, wherein said updating a battery impedance table comprises at least one of directly updating, filtering, averaging, interpolating, or confidence determining using the determined impedance.

6. The method of claim 1, further comprising:
calculating a state of charge of the battery using the updated battery impedance table.

7. A system for tracking aging effect on battery impedance, comprising:
a voltage measuring device configured to determine a first voltage of a battery associated with a first state of the battery and a second voltage of the battery associated with a second state of the battery; and
a processing circuit configured to
detect a state change in the battery that corresponds to the second state of the battery having a known current consumption level,
determine an impedance of the battery based at least on the first voltage, the second voltage, and the known current consumption level, and
update a battery impedance table that is used for calculating a state of charge of the battery using the determined impedance.

8. The system of claim 7, wherein the processing circuit is further configured to monitor the battery in the first state for a period of time prior to determining the first voltage of the battery, the period of time being dependent on a charge level of the battery.

9. The system of claim 7, wherein the battery is a lithium battery.

10. The system of claim 7, wherein the first state is an idle state of the battery.

11. The system of claim 7, wherein the processing circuit is configured to update the battery impedance table by at least one of directly updating, filtering, averaging, interpolating, or confidence determining using the determined impedance.

12. The system of claim 7, wherein the processing circuit is further configured to calculate a state of charge of the battery using the updated battery impedance table.

13. A method for tracking battery state of health, comprising:
tracking charges associated with partial charging cycles or charges associated with partial discharging cycles subsequent to a first event to generate cumulative charge data for a battery; and
calculating a new state of health estimation for the battery after a second event if the cumulative charge data has a predetermined relationship with a predetermined threshold.

14. The method of claim 13, wherein the first event is a battery empty event and the second event is a battery full event.

15. The method of claim 14, wherein said tracking comprises:
tracking a cumulative charging charge of the battery by counting charges entering the battery that are associated with partial charging cycles.

16. The method of claim 13, wherein the first event is a battery full event and the second event is a battery empty event.

17. The method of claim 16, wherein said tracking comprises:
tracking a cumulative discharging charge of the battery by counting charges leaving the battery that are associated with partial discharging cycles.

18. The method of claim 13, wherein said calculating comprises:
calculating the new state of health estimation based on the cumulative charge data if the cumulative charge of the battery is less than the predetermined threshold.

19. The method of claim 13, wherein the predetermined threshold is equivalent to a multiple of a charge cycle.

20. A system for tracking battery state of health according to the method of claim 13.
